(19) United States
(12) Patent Application Publication
(10) Pub. No.: US 2017/0095807 A1
(43) Pub. Date: Apr. 6, 2017

(54) FORMING AGE-SUPPRESSING CATALYSTS

(71) Applicant: GM GLOBAL TECHNOLOGY OPERATIONS LLC, DETROIT, MI (US)

(72) Inventors: Xingcheng Xiao, Troy, MI (US); Gongshin Qi, Troy, MI (US); Ryan J. Day, Waterford, MI (US)

(21) Appl. No.: 15/247,601

(22) Filed: Aug. 25, 2016

Related U.S. Application Data
(60) Provisional application No. 62/237,405, filed on Oct. 5, 2015.

(51) Int. Cl. B01J 37/00; B01J 37/02; B01J 37/08; B01J 37/03; B01J 35/00; B01J 35/06; B01J 35/04; B01J 23/40; C23C 16/455; B29C 47/00; C23C 16/40; F01N 3/10; B01D 53/94; F01N 3/28; B01J 37/34

(52) U.S. Cl. CPC B01J 37/0018; B01J 37/348; B01J 37/0215; B01J 37/082; B01J 37/088; B01J 37/035; B01J 35/0006; B01J 35/06; B01J 35/0013; B01J 35/04; B01J 23/40; C23C 16/45555; B29C 47/0004; B29C 47/0014; B29C 47/0076; C23C 16/40; F01N 3/103; F01N 3/101; B01D 53/945; B01D 53/944; F01N 3/2825; B29L 2023/00

(57) ABSTRACT

In an example of a method for forming a catalyst, a polymeric solution including a platinum group metal (PGM) is exposed to electrospinning to form carbon-based nanofibers containing PGM nanoparticles therein. An outer surface of the carbon-based nanofibers containing the PGM nanoparticles is coated with a metal oxide or a metal oxide precursor. The carbon-based nanofibers are selectively removed to form metal oxide nanotubes having PGM nanoparticles retained within a hollow portion thereof.

### CROSS-REFERENCE TO RELATED APPLICATIONS

This application claims the benefit of U.S. Provisional Application Ser. No. 62/237,405, filed Oct. 5, 2015, which is incorporated by reference herein in its entirety.

### TECHNICAL FIELD

The present disclosure relates generally to catalysts, and more specifically to methods for forming age-suppressing catalysts.

### BACKGROUND

Vehicles with an Internal Combustion Engine (ICE) include an exhaust gas treatment system for treating the exhaust gas from the engine. The configuration of the treatment system depends, in part, upon whether the engine is a diesel engine (which typically operates with lean burn combustion and contains high concentrations of oxygen in the exhaust gases at all operating conditions) or a stoichiometric spark-ignited engine (which operates at a nearly stoichiometric air-to-fuel (A/F) ratio). The treatment system for the diesel engine includes a diesel oxidation catalyst (DOC), which is capable of oxidizing carbon monoxide (CO) and hydrocarbons (HC). The treatment system for the stoichiometric spark-ignited engine includes a three-way catalyst (TWC), which operates on the principle of non-selective catalytic reduction of NOₓ by CO and HC.

### SUMMARY

In an example of a method for forming a catalyst, a polymeric solution including a platinum group metal (PGM) is exposed to electrospinning to form carbon-based nanofibers containing PGM nanoparticles therein. An outer surface of the carbon-based nanofibers containing the PGM nanoparticles is coated with a metal oxide or a metal oxide precursor. The carbon-based nanofibers are selectively removed to form metal oxide nanotubes having PGM nanoparticles retained within a hollow portion thereof.

### BRIEF DESCRIPTION OF THE DRAWINGS

Features of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 is a schematic illustration depicting two mechanisms for PGM particle growth or sintering;

FIG. 2 is a cut-away schematic view depicting an example of a catalyst disclosed herein, both before and after vapor phase migration (VPM);

FIGS. 3A through 3D are schematic views which depict an example of a method for forming the catalyst disclosed herein;

FIG. 4 is a schematic depiction of electrospinning (i.e., electric field (E) spinning) to form carbon-based nanofibers containing PGM nanoparticles therein;

FIG. 5A is a perspective, partially cut-away view of an example of a catalytic converter; and

FIG. 5B is an enlarged view of a portion of FIG. 5A.

### DETAILED DESCRIPTION

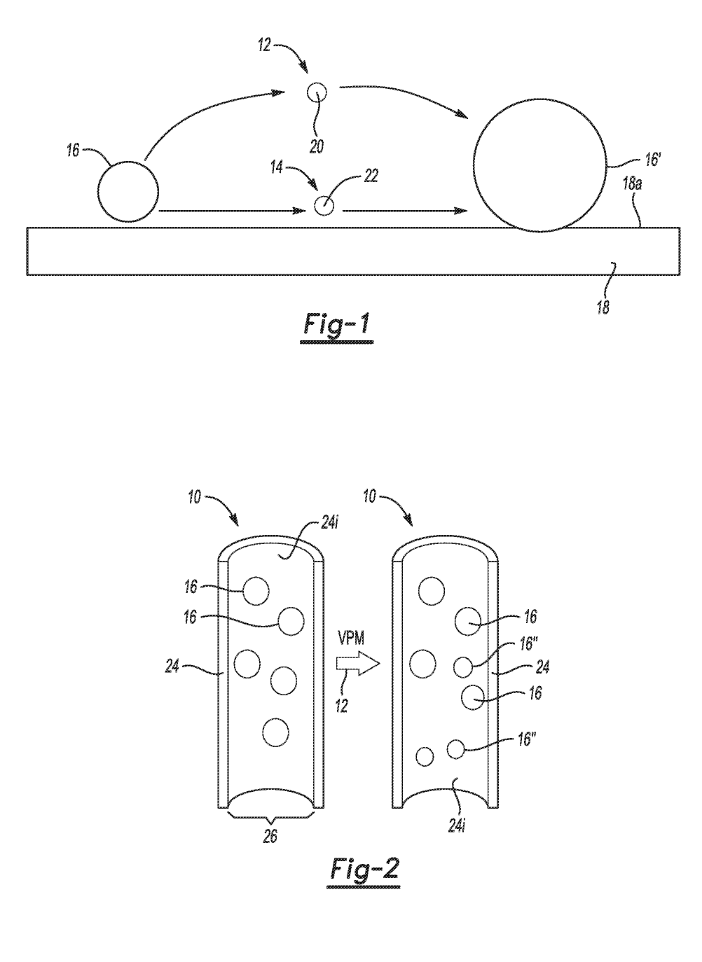

DOCs and TWCs often include a support loaded with a Platinum Group Metal (PGM) as the active catalytic/catalyst material. As the exhaust gas temperature from the vehicle engine increases (e.g., to temperatures ranging from 150° C. to about 1000° C.), the PGM loaded on the support may experience particle growth (i.e., sintering). FIG. 1 depicts two mechanisms for PGM particle growth during vehicle operation. The mechanisms involve atomic and/or crystallite PGM migration. The first mechanism involves PGM migration via a vapor phase, denoted 12, and the second mechanism involves PGM migration via surface diffusion, denoted 14. In the first mechanism, a mobile species (not shown), emitted from the PGM particles 16 loaded on the support 18, can travel through the vapor phase 12 and agglomerate with other metal particles 20 in the vapor phase 12 to form larger PGM particles 16′. In the second mechanism, a mobile species (not shown) emitted from the PGM particles 16 can diffuse along the surface 18a of the support 18 and agglomerate with other metal particles 22 on the surface 18a to form larger PGM particles 16′.

An increase in the size of the PGM particles 16′ results in poor PGM utilization and undesirable aging of the catalyst material. More specifically, the increased particle size reduces the PGM dispersion, which is a ratio of the number of surface PGM atoms in the catalyst to the total number of PGM atoms in the catalyst. A reduced PGM dispersion is directly related to a decrease in the active metal surface area (as a result of particle growth), and thus indicates a loss in active catalyst reaction sites. The loss in active catalyst reaction sites leads to poor PGM utilization efficiency, and indicates that the catalyst has undesirably been aged or deactivated.

It has been observed that about 1% of the PGM in a typical TWC remains catalytically active after 100,000 to 150,000 miles of driving (i.e., 99% of the PGM is wasted). One approach to counteract the effect of sintering is to use a high enough PGM loading to compensate for the catalyst deactivation. However, this increases the cost of the TWC.

The catalysts disclosed herein suppress aging/deactivation by retaining the PGM particles 16 within a hollow portion of a nanotube (which function as the support 18 for the PGM particles 16). The catalyst 10 is shown in FIG. 2.

As depicted in FIG. 2, the catalyst 10 includes a metal oxide nanotube 24 and the PGM particles 16 retained within a hollow portion 26 of the metal oxide nanotube 24.

The metal oxide nanotube 24 may be any ceramic material that is commonly used in catalytic converters, such as Al₂O₃, CeO₂, ZrO₂, CeO₂—ZrO₂, SiO₂, TiO₂, MgO, ZnO, BaO, K₂O, Na₂O, CaO, and combinations thereof. When initially formed via the method disclosed herein (described below), the length of the nanotubes 24 may be up to 1 mm (millimeter). If desirable for the catalyst application, the longer nanotubes 24 may be cut up into smaller nanotubes 24 having a length ranging from about 100 nm (nanometer) to about 10 μm (micrometer). The outer diameter of the nanotube 24 may range from about 10 nm to about 1 μm. The inner diameter (i.e., the diameter of the hollow portion 26) of the nanotube 24 may range from about 2 nm to about 900 nm.

As depicted, the PGM particles 16 are retained within the hollow portion 26 of the nanotube 24. As a result of the method disclosed herein, the PGM particles 16 may be physically attached to the interior surface 24i of the metal oxide nanotube 24 and/or may be partially embedded in the interior surface 24i of the metal oxide nanotube 24. As depicted, the PGM particles 16 may be distributed on and along the interior surface (inner wall) 24i of the nanotube 24.

The PGM particles 16 are formed of active catalytic material, and may be palladium (Pd), platinum (Pt), rhodium (Rh), ruthenium (Ru), osmium (Os), iridium (Ir), or various combinations thereof (e.g., Pd and Pt, Pt and Rh, Pd and Rh, Pd, Pt and Rh, Pt and Ir, Pd and Os, or any other combination). The PGM particles 16 are present in the catalyst 10 in an amount ranging from about 0.1 wt % to about 10 wt % of the catalyst 10. When initially formed, the PGM particles 16 are nanoparticles that have at least one dimension on the nanoscale (ranging from about 1 nm to about 100 nm).

As mentioned above, the PGM particles 16 can vaporize at high temperatures (e.g., when exposed to exhaust gas). FIG. 2 depicts the catalyst 10 before (left side) and after (right side) vapor phase migration 12, VPM resulting from exhaust gas and high temperature exposure. The exhaust gases may pass through the hollow portion 26 of the nanotubes 24, where the gases are exposed to the PGM particles 16. During vapor phase migration 12, the interior surface 24i of the nanotube 24 provides a physical barrier which can capture PGM vapors. The mobile species in the captured vapors agglomerate to form new PGM nanoparticles 16″ within the nanotube 24 (shown on the right side of FIG. 2). The newly formed PGM nanoparticles 16″ may be smaller than the PGM particles 16, and provide additional active PGM sites for catalysis.

The interior surface 24i can also suppress vapor phase migration (by the condensation of PGM vapor on the inner wall 24i) and surface diffusion from one nanotube 24 to the next nanotube 24. The configuration of the catalysts 10 disclosed herein slows down or prevents the PGM particle 16 growth/sintering and maintains more active PGM sites over time, and thus the catalyst 10 ages relatively slowly. Moreover, when sintering is reduced or prevented, the operational temperature of the catalyst 10 is prevented from drifting upward over time.

The catalyst 10 disclosed herein may be formed via a method that utilizes sacrificial carbon-based nanofibers to form the metal oxide nanotubes 24 and to position the PGM particles 16 with the hollow portion 26 of the metal oxide nanotube 24. Generally, the method involves electrospinning a polymeric solution including a platinum group metal (PGM) to form carbon-based nanofibers containing PGM nanoparticles 16 therein; coating an outer surface of the carbon-based nanofibers containing the PGM nanoparticles 16 with a metal oxide or a metal oxide precursor; and selectively removing the carbon-based nanofibers to form the metal oxide nanotubes 24 having PGM nanoparticles 16 retained within the hollow portion 24.

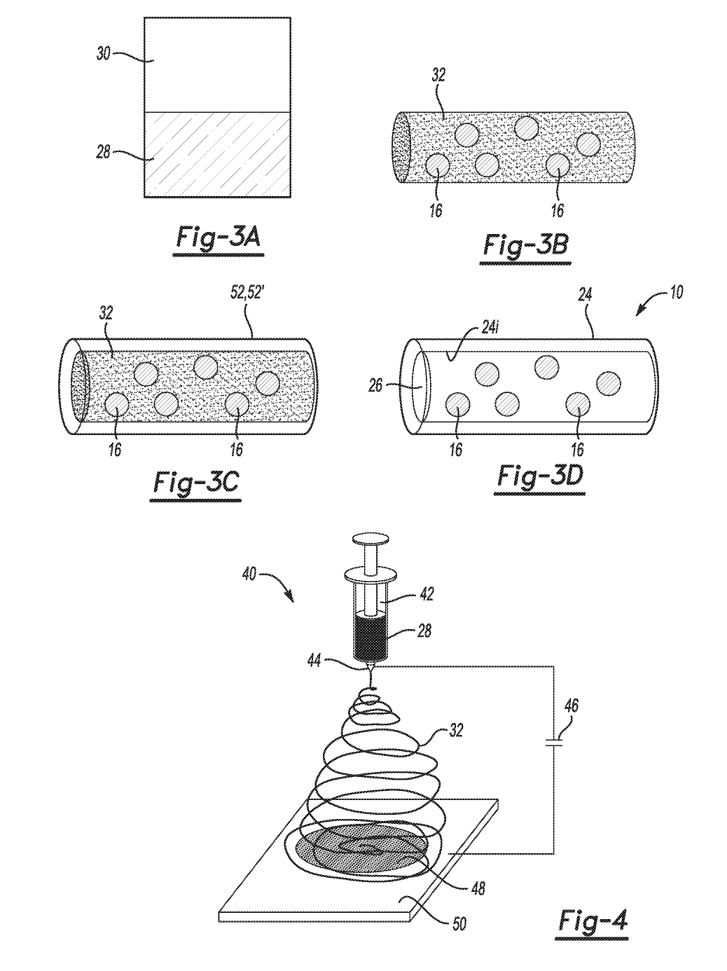

An example of the method is shown schematically in FIGS. 3A through 3D.

In FIG. 3A a polymer solution 28 is prepared/formed in a vessel 30. To form the polymer solution 28, a PGM solution is mixed with a polymer in a solvent. The PGM solution may be an aqueous solution that includes a PGM precursor dissolved or dispersed in water. As one example, the polymer solution 28 is formed by mixing chloroplatinic acid hydrate (H₂PtCl₆·xH₂O) with polyacrylonitrile (PAN) in dimethylformamide (DMF). Other polymer solutions 28 may be formed using different PGM solutions, different polymers and/or different solvents. Examples of other suitable PGM solutions include a platinum nitrate solution, a platinum(II) chloride solution, a platinum acetate solution, a palladium nitrate solution, a palladium acetate solution, a rhodium nitrate solution, a rhodium acetate solution, or combinations thereof. PGM precursor solutions of ruthenium, osmium, and/or iridium may also be used. Examples of other suitable polymers include polypropylene (PP), polyethylene (PE), polyethylene terephthalate (PET), poly(methyl methacrylate) (PMMA), poly(3,4-ethylenedioxythiophene) polystyrene sulfonate (PEDOT:PSS), polypyrrole (PPy), poly(p-phenylene vinylene) (PPV or polyphenylene vinylene), and polyethylene oxide (PEO or polyoxyethylene (POE)). An example of another suitable solvent is chloroform.

In the polymer solution 28, the volume ratio of the PGM solution to the polymer ranges from 1% (1:100) to 10% (1:10).

The method continues with electrospinning the polymer solution 28 to form carbon-based nanofibers 32 containing PGM particles 16 therein. An example of electrospinning is shown in FIG. 4, and an example of the resulting carbon-based nanofibers 32 are shown in FIGS. 3A and 3B.

Electrospinning, i.e., E-spinning or electric field spinning, relates to spinning a nanofiber in an electric field. The electric force draws charged threads of the polymer solution 28 up to suitable fiber diameters. Examples of suitable fiber diameters range from about 2 nm up to 1 μm.

An example of an E-spin apparatus 40 used to perform electrospinning is shown in FIG. 4. The E-spin apparatus 40 includes a device 42, such as a syringe, for dispensing a fluid, such as the polymer solution 28, through a capillary tip 44. The polymer solution 28 forms the carbon nanofiber 32 (having the PGM particles 16 therein) in the presence of a high electric field generated by a high voltage source 46. In an example, the electric field ranges from about 100 V to about 50,000 V, or even higher. In another example, the electric field ranges from about 100 V to about 1,000 V.

The high voltage source 46 is connected to electrodes of the apparatus 40. The capillary tip 44 forms one electrode and a conductive plate 50 forms the counter electrode. Each of the capillary tip 44 and the conductive plate 50 may be formed on any suitable electrode material, such as copper (Cu), aluminum (Al), stainless steel, etc. The conductive plate 50 may also include a mat 48, which sits on the conductive plate 50 and can collect the carbon nanofiber 32 as it is formed.

During electrospinning, the polymer in the polymer solution 28 forms the carbon nanofiber 32 and the PGM from the PGM solution forms the PGM particles 16 distributed throughout the interior of the carbon nanofiber 32.

There are several factors that can be varied to control the final physical properties of the carbon nanofiber 32, such as its diameter. These factors include controlling the diameter of the capillary tip 44 (which can change the diameter of the fiber 32), the distance between the capillary tip 44 and the mat 48 (which can change the length and density of the fiber), the voltage generated by the high voltage source 46 (which can change the diameter of the fiber), and/or controlling the composition of the polymer solution 28 (which can affect the composition of the fiber 32 and/or the PGM particle 16 that is formed). As one example, a capillary tip 44 with a larger diameter forms a carbon-based nanofiber 32 with a larger diameter. As another example, a shorter distance between the capillary tip 44 and the mat 48 forms a carbon-based nanofiber 32 with a smaller diameter. As still another example, a higher voltage forms a carbon-based nanofiber 32 with a larger diameter. As yet another example, a polymer solution 28 having a higher concentration of PGM precursor (e.g., PGM salt) forms a carbon-based nanofiber 32 with a higher loading of PGM nanoparticles 16 formed on the interior surface 24i.

Once the electrospun carbon nanofiber 32 is collected, its outer surface is coated, as shown in FIG. 3C. In one example, the outer surface is coated with a metal oxide to form a metal oxide (or ceramic) coating 52. In another example, the outer surface is coated with a metal oxide precursor to form a metal oxide precursor coating 52′. The metal oxide may be Al₂O₃, CeO₂, or any other metal oxide commonly used in catalytic converters, such as ZrO₂, CeO₂—ZrO₂, SiO₂, TiO₂, MgO, ZnO, BaO, K₂O, Na₂O, CaO, and combinations of any of the metal oxides. The metal oxide precursor may be any of the salts of the metals of the metal oxide, as discussed below.

The metal oxide coating 52 may be formed on the carbon-based nanofibers 32 containing PGM nanoparticles 16 therein by any suitable process, such as atomic layer deposition (ALD). The metal oxide precursor coating 52′ may be formed on the carbon-based nanofibers 32 containing PGM nanoparticles 16 therein by any suitable process, such as precipitation.

In one example, the metal oxide coating 52 is formed via atomic layer deposition (ALD). To form an Al₂O₃ metal oxide coating 52 via ALD, the starting components may include trimethyl aluminum and water. The starting components may be varied to form other metal oxide coatings 52. The overall reaction for forming Al₂O₃ via ALD is shown is shown as reaction (1) and the half-reactions are shown as reactions (2) and (3):

2Al(CH₃)₃+3H₂O→Al₂O₃+6CH₄ (1)

Al(CH₃)_{3(g)}+:Al—O—H₍ₛ₎→:Al—O—Al(CH₃)₂₍ₛ₎+CH₄ (2)

2H₂O_{(g)}+:O—Al(CH₃)₂₍ₛ₎→:Al—O—Al(OH)₂₍ₛ₎+2CH₄. (3)

The reaction during ALD relies on the presence of —OH bonds on the surface of the carbon-based nanofibers 32. The nature of the ALD process is that it deposits one monolayer per cycle. Over many cycles, alternating layers of oxygen and aluminum are formed, resulting in a hydroxylated Al₂O₃ surface. ALD is a self-limiting surface reaction process. For example, in the first half cycle, Al(CH₃)₃ reacts with —OH groups on the carbon-based nanofibers 32, and forms Al—(CH)₂. Then, water is introduced, which reacts with Al—(CH)₂ and forms Al—OH again. After this, one cycle is completed and a layer of Al₂O₃ is formed. The process is repeated to form several layers of Al₂O₃ and to create the metal oxide coating 52.

In another example, the metal oxide precursor coating 52 is formed via a precipitation method. The precipitation method may involve precipitating a metal salt in the presence of the carbon-based nanofibers 32 containing the PGM particles 16. Any salt of the metal of the desired metal oxide for the nanotube 24 that is to be formed may be used. In an example, the metal salt is aluminum hydroxide (Al(OH)₃), which may be used to form an Al(OH)₃ coating 52′ and ultimately an Al₂O₃ nanotube 24. Other suitable salts for ultimately forming an Al₂O₃ nanotube 24 include aluminum nitrate (Al(NO₃)₃), aluminum chloride (AlCl₃), aluminum sulfate (Al₂(SO₄)₃), aluminum phosphate (AlPO₄), and/or aluminum bromide (Al₂Br₆, AlBr₃). Suitable salts for forming a ZrO₂ nanotube 24 include zirconium nitrate (Zr(NO₃)₄), zirconium chloride (ZrCl₄), zirconium bromide (ZrBr4), zirconium sulfate (Zr(SO₄)₂), zirconium(IV) oxynitrate hydrate (ZrO(NO₃)₂·xH₂O), and/or zirconium(IV) hydroxide (Zr(OH)₄). Suitable salts for forming a CeO₂ nanotube 24 include cerium(III) bromide (CeBr₃), cerium(III) chloride (CeCl₃), cerium(III) nitrate (Ce(NO₃)₃), and/or cerium(III) sulfate (Ce₂(SO₄)₃). Similar silicon salts, titanium salts, magnesium salts, zinc salts, barium salts, potassium salts, sodium salts, and calcium salts may be used to form SiO₂, TiO₂, MgO, ZnO, BaO, K₂O, Na₂O, and CaO nanotubes 24, respectively.

In an example of the precipitation method, the salt or a mixture of salts is dissolved in water, and then the fibers 32 (containing the PGM particles 16) are immersed into the solution. By drying the water, the salt will precipitate on the fiber surface. During the selective removal of the fibers 32 (which may involve heating in the presence of oxygen), the salt converts into the oxide while the fiber 32 is burning away.

Referring now to FIG. 3D, the method continues with selectively removing the carbon-based nanofibers 32. In some examples, the selective removal process removes the carbon-based nanofibers 32, and thus hollows out the metal oxide coating 52. This forms the metal oxide nanotube 24 with the hollow portion 26. While this example of the selective removal process removes the carbon-based nanofibers 32, it leaves the PGM particles 16 and the metal oxide from the coating 52 intact as the nanotube 24. In other examples, the selective removal process converts the metal oxide precursor coating 52′ to a metal oxide and removes the carbon-based nanofibers 32. This forms the metal oxide nanotube 24 with the hollow portion 26. While this example of the selective removal process removes the carbon-based nanofibers 32 and converts the metal oxide precursor (e.g., metal salt) to the metal oxide, it leaves the PGM particles 16 intact.

Selective removal of the carbon-based nanofibers 32 may be accomplished by burning the carbon nanofiber 32. Burning may be performed to get rid of the carbon nanofiber 32 without deleteriously affecting the PGM particles 16 or the metal oxide in the coating 52. Burning may also be performed to get rid of the carbon nanofiber 32 and to convert the metal oxide precursor in the coating 52′ to the metal oxide without deleteriously affecting the PGM particles 16. Burning may also enable the PGM particles 16 to contact and adhere to and/or becoming partially embedded in the interior surface 24i of the nanotube 24. In some examples, the carbon nanofiber(s) 32 will burn off in air or oxygen at a temperature of, or above, 400° C.

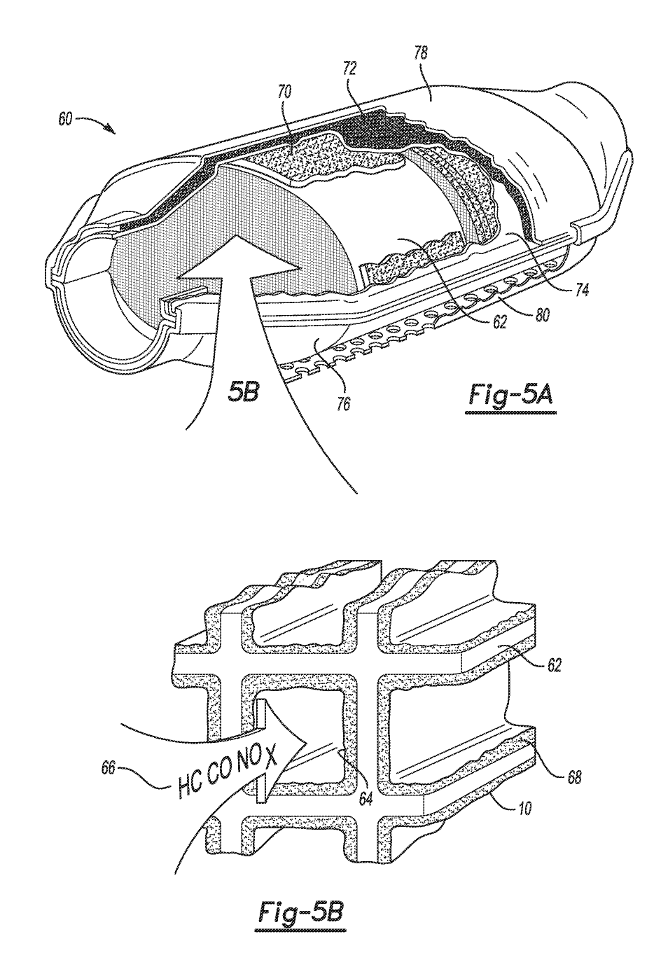

The method(s) disclosed herein may be used to suppress aging of the PGM particles 16 in a catalytic converter. For example, the metal oxide nanotubes 24 having the PGM particles 16 retained within the hollow potions 26 thereof are formed as previously described, and then these nanotubes 24 are incorporated as a catalyst 10 into the catalytic converter. For incorporation into the catalytic converter, the catalyst 10 may be applied to a monolith substrate and utilized in the catalytic converter. An example of the catalytic converter is shown in FIG. 5A and an example of the monolith substrate is shown in both FIGS. 5A and 5B.

The catalytic converter 60 includes the monolith substrate 62. The monolith substrate 62 may be formed of a ceramic or a metal alloy that is capable of withstanding high temperatures (e.g., 100° C. or higher). Synthetic cordierite is a magnesium-alumino-silicate ceramic material that is suitable for use as the monolith substrate 62. A ferritic iron-chromium-aluminum alloy is an example of a metal alloy that is suitable for use as the monolith substrate 62. The monolith substrate 62 has a honeycomb or other three-dimensional structure.

An enlarged view of a portion of the monolith substrate 62 is depicted in FIG. 4B. The monolith substrate 62 includes a large number of parallel flow channels 64 to allow for sufficient contact area between the exhaust gas 66 and the catalyst 10 (contained in coating 68) without creating excess pressure losses.

The coating 68 includes the catalyst 10 disclosed herein. In some instances, the coating 36 may also include a binder material (e.g., sol binders or the like). The coating 68 may be applied to the monolith substrate 62 by washcoating or some other similar processes.

Referring back to FIG. 5A, in the catalytic converter 60, the monolith substrate 62 (with the coating 68 thereon) is surrounded by a mat 70, which in turn is surrounded by insulation 72. Upper and lower shells 74, 76 (formed of metal) may be positioned between the mat 70 and the insulation 72. An insulation cover 78 may be positioned over the upper shell 74 and the insulation 72 thereon, and a shield 80 may be positioned adjacent to the lower shell 76 and the insulation 72 thereon.

The catalytic converter 60 may be a DOC, which is used in a diesel engine. The DOC is a two way catalytic converter, which eliminates hydrocarbons and CO by oxidizing them, respectively, to water and CO₂. The DOC may also exhibit NOₓ storage capability during the vehicle cold-start period. In such diesel engines, the reduction of NOₓ to water and N₂ may take place in a separate unit, and may involve the injection of urea into the exhaust.

The catalytic converter 60 may also be a TWC, which is used in a stoichiometric spark-ignited engine. The TWC is a three way catalytic converter, which reduces NOx to N₂, and oxidizes HC and CO, respectively, to water and CO₂.

It is to be understood that the ranges provided herein include the stated range and any value or sub-range within the stated range. For example, a range of from about 150° C. to about 1000° C. should be interpreted to include not only the explicitly recited limits of from about 150° C. to about 1000° C., but also to include individual values, such as 125° C., 580° C., etc., and sub-ranges, such as from about 315° C. to about 975° C., etc. Furthermore, when “about” is utilized to describe a value, this is meant to encompass minor variations (up to +/−10%) from the stated value.

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

In describing and claiming the examples disclosed herein, the singular forms “a”, “an”, and “the” include plural referents unless the context clearly dictates otherwise.

While several examples have been described in detail, it is to be understood that the disclosed examples may be modified. Therefore, the foregoing description is to be considered non-limiting.

1. A method for forming a catalyst, the method comprising:
electrospinning a polymeric solution including a platinum group metal (PGM), thereby forming carbon-based nanofibers containing PGM nanoparticles therein;
coating an outer surface of the carbon-based nanofibers containing the PGM nanoparticles with a metal oxide or a metal oxide precursor; and
selectively removing the carbon-based nanofibers, thereby forming metal oxide nanotubes having PGM nanoparticles retained within a hollow portion thereof.

2. The method as defined in claim 1, further comprising forming the polymeric solution by mixing a PGM solution with a polymer in a solvent.

3. The method as defined in claim 2 wherein:
the PGM solution is selected from the group consisting of a chloroplatinic acid solution, a platinum nitrate solution, a platinum(II) chloride solution, a platinum acetate solution, a palladium nitrate solution, a palladium acetate solution, a rhodium nitrate solution, a rhodium acetate solution, or combinations thereof;
the polymer is selected from the group consisting of polyacrylonitrile (PAN), polypropylene (PP), polyethylene (PE), polyethylene terephthalate (PET), poly(methyl methacrylate) (PMMA), poly(3,4-ethylenedioxythiophene) polystyrene sulfonate (PEDOT:PSS), polypyrrole (PPy), poly(p-phenylene vinylene) (PPV), and polyethylene oxide (PEO); and
the solvent is selected from the group consisting of dimethylformamide (DMF) and chloroform.

4. The method as defined in claim 1 wherein:
the selectively removing of the carbon-based nanofibers is accomplished by burning off the carbon-based nanofibers; and
one of:
the PGM nanoparticles and the metal oxide remain intact; or
the PGM nanoparticles remain intact and the metal oxide precursor is converted to a metal oxide to form the metal oxide nanotubes.

5. The method as defined in claim 4 wherein the burning off of the carbon-based nanofibers is accomplished in air or in oxygen at a temperature of or above 400° C.

6. The method as defined in claim 1 wherein the electrospinning involves dispensing the polymeric solution through a capillary tip in the presence of an electric field generated by a voltage source.

7. The method as defined in claim 6 wherein:
the voltage source is connected to an electrode and a counter electrode;
the capillary tip forms the electrode;
a conductive plate forms the counter electrode; and
the conductive plate collects the carbon-based nanofibers containing the PGM nanoparticles as they are formed.

8. The method as defined in claim 7, further comprising controlling a property of the carbon-based nanofibers containing the PGM nanoparticles by controlling:
a diameter of the capillary tip;
a distance between the capillary tip and the conductive plate;
the electric field generated by the voltage source; and
a composition of the solution.

9. The method as defined in claim 6 wherein the electric field ranges from about 100 V to about 50,000 V.

10. The method as defined in claim 1 wherein the metal oxide is selected from the group consisting of Al₂O₃, CeO₂, ZrO₂, CeO₂—ZrO₂, SiO₂, TiO₂, MgO, ZnO, BaO, K₂O, Na₂O, CaO, and combinations thereof.

11. The method as defined in claim 1 wherein the coating of the outer surface with the metal oxide is accomplished by atomic layer deposition (ALD).

12. The method as defined in claim 1 wherein the coating of the outer surface with the metal oxide precursor is accomplished by precipitating a metal salt in the presence of the carbon-based nanofibers containing the PGM nanoparticles.

13. The method as defined in claim 12 wherein the metal salt is selected from the group consisting of aluminum hydroxide (Al(OH)₃), aluminum nitrate (Al(NO₃)₃), aluminum chloride (AlCl₃), aluminum sulfate (Al₂(SO₄)₃), aluminum phosphate (AlPO₄), aluminum bromide (Al₂Br₆, AlBr₃), zirconium nitrate (Zr(NO₃)₄), zirconium chloride (ZrCl₄), zirconium bromide (ZrBr4), Zirconium sulfate (Zr(SO₄)₂), zirconium(IV) oxynitrate hydrate (ZrO(NO₃)₂·xH₂O), zirconium(IV) hydroxide (Zr(OH)₄), cerium(III) bromide (CeBr₃), cerium(III) chloride (CeCl₃), cerium(III) nitrate (Ce(NO₃)₃), cerium(III) sulfate (Ce₂(SO₄)₃), and combinations thereof.

14. A method for suppressing aging of platinum group metal (PGM) nanoparticles in a catalytic converter, the method comprising:
electrospinning a polymeric solution including a platinum group metal (PGM), thereby forming carbon-based nanofibers containing the PGM nanoparticles therein;
coating an outer surface of the carbon-based nanofibers containing the PGM nanoparticles with a metal oxide or a metal oxide precursor;
selectively removing the carbon-based nanofibers, thereby forming metal oxide nanotubes having PGM nanoparticles retained within a hollow portion thereof; and
incorporating the metal oxide nanotubes having the PGM nanoparticles retained within the hollow portion thereof as a catalyst in the catalytic converter.

15. The method as defined in claim 14 wherein the incorporating is accomplished by:
applying the metal oxide nanotubes having the PGM nanoparticles retained within the hollow portion thereof on interior surfaces of a honeycomb structure of a monolith substrate; and
incorporating the monolith substrate into the catalytic converter.

16. The method as defined in claim 14, further comprising forming the polymeric solution by mixing a PGM solution with a polymer in a solvent, wherein:
the PGM solution is selected from the group consisting of a chloroplatinic acid solution, a platinum nitrate solution, a platinum(II) chloride solution, a platinum acetate solution, a palladium nitrate solution, a palladium acetate solution, a rhodium nitrate solution, a rhodium acetate solution, or combinations thereof;
the polymer is selected from the group consisting of polyacrylonitrile (PAN), polypropylene (PP), polyethylene (PE), polyethylene terephthalate (PET), poly(methyl methacrylate) (PMMA), poly(3,4-ethylenedioxythiophene) polystyrene sulfonate (PEDOT:PSS), polypyrrole (PPy), poly(p-phenylene vinylene) (PPV), and polyethylene oxide (PEO); and
the solvent is selected from the group consisting of dimethylformamide (DMF) and chloroform.

17. The method as defined in claim 14 wherein:
the selectively removing of the carbon-based nanofibers is accomplished by burning off the carbon-based nanofibers in air or in oxygen at a temperature of or above 400° C.; and
one of:
the PGM nanoparticles and the metal oxide remain intact; or
the PGM nanoparticles remain intact and the metal oxide precursor is converted to a metal oxide to form the metal oxide nanotubes.

18. The method as defined in claim 14 wherein the electrospinning involves dispensing the polymeric solution through a capillary tip in the presence of an electric field generated by a voltage source, wherein the electric field ranges from about 100 V to about 50,000 V.

19. The method as defined in claim 14 wherein the coating of the outer surface with the metal oxide is accomplished by atomic layer deposition (ALD).

20. The method as defined in claim 14 wherein the coating of the outer surface with the metal oxide precursor is accomplished by precipitating a metal salt in the presence of the carbon-based nanofibers containing the PGM nanoparticles.
